(19) United States
(12) Patent Application Publication
(10) Pub. No.: US 2026/0259249 A1
(43) Pub. Date: Sep. 3, 2026

(54) DEVICE AND METHOD FOR INSPECTING AND/OR MONITORING CURRENT IN A PHASE

(71) Applicant: Siemens Aktiengesellschaft, 80333 München (DE)

(72) Inventors: THOMAS JUNGWIRTH, Forchheim (DE); ANDREAS KUNERT, Oberasbach (DE); ROLAND LORZ, Röttenbach (DE); LUTZ NAMYSLO, Hausen (DE)

(73) Assignee: Siemens Aktiengesellschaft, 80333 München (DE)

(21) Appl. No.: 18/993,151

(22) PCT Filed: Jul. 3, 2023
(86) PCT No.: PCT/EP2023/068197

§ 371 Date: Jan. 10, 2025

(30) Foreign Application Priority Data
Jul. 13, 2022 (EP) 22184707.2

(51) Int. Cl. G01R 19/10; G01R 19/25

(52) U.S. Cl. CPC G01R 19/10; G01R 19/25

(57) ABSTRACT

A device inspects and/or monitors phase currents in a power electronics device that has at least two power semiconductor modules that are connected in parallel on the phases. The device comprises at least two current detection devices, at least two conversion units, and an evaluation apparatus. Each current detection device is designed to detect a partial current at each power semiconductor module and output an analogue signal corresponding to the detected partial current. A sum of the detected partial currents gives the current in the phase. Each conversion unit is connected downstream of a respective current detection device and is designed to convert the analogue signal into a digital signal. The evaluation apparatus is connected downstream of the at least two conversion units and designed and configured to generate, based on the digital signals, an output signal which contains control-relevant and/or diagnostics-relevant information about the current in the phase.

The invention relates to an apparatus and a method for inspecting and/or monitoring current in a phase in a power electronics apparatus, preferably in a converter, for example in a power converter, in particular in an inverter or in a frequency converter, wherein the power electronics apparatus has at least two power semiconductor modules, wherein the at least two power semiconductor modules are connected in parallel on the phase, wherein the apparatus comprises at least two current detection apparatuses, at least two conversion units and an evaluation facility, wherein each current detection apparatus is embodied to detect a partial current at a respective power semiconductor module of the power semiconductor modules connected in parallel on the phase and to output an analog signal which corresponds to the detected partial current, wherein a sum of all detected partial currents is produced in the current in the phase, wherein each conversion unit is in each case connected downstream of a current detection apparatus and is embodied to convert the analog signal into a digital signal, wherein the evaluation facility is connected downstream of the at least two conversion units.

Moreover, the invention relates to an electronic assembly with such an apparatus.

In addition, the invention relates to a power electronics apparatus, in particular a converter, in particular a frequency converter or inverter with such an electronic assembly.

To operate the current control in power electronics apparatuses, the actual current value of the current phase is required, in particular of each individual current phase if multi-phase operation is possible. Herein, the current output, for example the actual current value of a phase, or the actual current value of a DC/DC converter, which can also be a singl s measured.

To increase the power of frequency converters, parallel connection of a plurality of power semiconductor modules (usually two to six, in exceptional cases up to a maximum of ten) is a common and established solution. Herein, the power and the current increase proportionally with the number of parallel-connected power semiconductor modules. This makes it possible, for example, to provide converters that can operate in a power range between 0.55 kW and 1.5 MW or more, in particular between 100 kW and 250.00 kW, preferably between 150 kW and 200 kW.

Herein, the phase current detection required to control the frequency converter is usually carried out via a central measuring transformer, i.e., one measuring transformer for each phase. Current transformers from, for example, the company LEM, for example from the HTA-S series of direct-imaging Hall effect current sensors, are well-known. However, many other commercial solutions are available on the market.

With a small number of power semi conductor modules connected in parallel (up to a maximum of three), decentralized detection of the currents (in the power semiconductor modules or in the immediate vicinity thereof) is also known, Le., detection of partial currents of the individual parallel-connected modules instead of the total phase current. This can take place, for example, using shunt measurement. “Immediate vicinity” means that the problem of EMC (electromagnetic compatibility) should be taken into account when attaching the shunts. In the context of the present disclosure, “immediate vicinity” may mean a few centimeters, for example 1 to 10 cm. The currents of each p ver semiconductor module detected in a decentralized manner can then be added via an analog circuit to obtain the total phase current. The analog addition of partial currents, in particular with high power and voltages and in combination with a shunt resistor measurement, is critical in terms of interference immunity and the transmission to the control unit. Analog addition of the currents of more than three power semiconductor modules is considered to be extremely complex and impractical.

However, the signal processing associated with these measurements (addition, transmission, etc.) is very susceptible to interference. In addition, in the first case, there is no information about how the currents are distributed within the parallel connection of the modules so that it is almost impossible to make a statement about the status of the corresponding individual power semiconductor modules. In the second case, analog addition provides inaccurate and unreliable measurement results.

An apparatus is known from patent application DE 10 2015 226 628 A1 (document D1) in which the partial currents are determined. However, a prerequisite for this is a direct measurement of the total current.

Application US 2022/149766 A1 (document D2) discloses a motor control apparatus. This comprises an inverter for driving a motor, a first shunt resistor connected to a first low-side switching element in the inverter, a second shunt resistor connected to a second low-side switching element in the inverter, a DC-link shunt resistor in series with the inverter and a controller for controlling the inverter based on a first current value measured through the first and second shunt resistors and a second current value measured through the DC-link shunt resistor.

A method and arrangement for controlling semiconductor power switches, for example IGBTs, in parallel-connected power devices, for example in frequency converters, are known from application US 2018/269805 A1 (document D3), wherein the semiconductor power switches connect either the positive or the negative pole of the intermediate DC voltage of the power device to an output phase of the power device. In the method, the voltages of the parallel-connected output phases are measured, the timing differences of the output voltage state changes are calculated on the basis of the output voltage measurement results and the control signals of the semiconductor power switches are advanced or delayed such that the output voltage state changes in the phases which are connected together via output impedances occur at desired times.

The application DE 10 2014 208 680 A1 relates to a method for monitoring current sensors when determining a total electric current I from a battery, preferably a lithium-ion battery, in an electric circuit having current sensors in a parallel circuit section with at least two parallel conduction paths for determining the respective partial currents and a further current sensor for determining the total current.

The present invention is therefore based on the object of providing apparatuses and methods that enable improved inspection and/or monitoring of the phase current, including partial currents.

The object is achieved according to the invention with an apparatus mentioned in the introduction in that the evaluation facility is embodied and configured to generate, based on the digital signals, at least one output signal which contains control-relevant and/or diagnostically relevant information about the current in the phase, wherein the evaluation facility has a digital addition component, wherein the digital addition component is configured to add the digital signals together so that the control-relevant information comprises the current value of the phase, wherein the diagnostically relevant information about the current in the phase comprises information about the symmetry of the division of the current in the phase into the partial currents.

The power electronics apparatus, preferably the converter, for example the power converter, in particular the inverter or the frequency converter, can, for example, be embodied to supply an electric machine, in particular a rotary machine, for example a three-phase asynchronous motor.

It is also conceivable for the power electronics apparatus to be embodied for mains operation, for example for power feeds or in DC-DC converter operation (transformer, mains, etc.)

Herein, each current detection apparatus is embodied to detect partial current in each case at or in a power semiconductor module, preferably at or in exactly one power semiconductor module, of the power semiconductor modules connected in parallel on the phase and to output an analog signal which corresponds to or represents the detected partial current. A sum of all detected partial currents is produced in the current in the phase—i.e., the total phase current.

Moreover, each conversion unit is in each case connected downstream of a current detection apparatus, preferably exactly one current detection apparatus, and is embodied to convert the analog signal into a digital signal. In an advantageous embodiment, each conversion unit is embodied to convert the analog signal into a serial digital signal with sigma-delta coding. The digital signal is preferably a 1-bit data stream.

The evaluation facility is connected downstream of the at least two conversion units. It is embodied and configured, based on the digital signals, to generate at least one output signal which bears control-relevant and/or diagnostically relevant information about the current in the phase—i.e., about the total current.

The evaluation facility is therefore embodied in terms of hardware to generate, based on the digital signals, at least one output signal which bears control-relevant and/or diagnostically relevant information about the current in the phase. This means that the evaluation facility has, for example, a sufficient number of pins, etc.

The evaluation facility is also configured in terms of software to generate, based on the digital signals, at least one output signal which bears control-relevant and/or diagnostically relevant information about the current in the phase, This means that the evaluation facility comprises, for example, program code (means) that enable it to generate at least one output signal based on the digital signals.

The evaluation facility therefore receives the (individual) digital signals as input and preferably converts them into the at least one output signal.

In the context of the present disclosure, the term “phase” should be understood to mean a phase conductor (also called an outer conductor).

For example, the AC supply system commonly used around the world today works with not one, but three, current-carrying conductors (outer conductors, phase conductors), wherein the phases of the individual currents with the same frequency are offset from each other by 120°. This is referred to as three-phase alternating current, three-phase current or heavy current. The individual conductors are typically referred to as U, V, and W or L1, L2, and L3 (sometimes also as R, S, and T).

In one embodiment, it may be provided that at least one power semiconductor module, preferably each power semiconductor module, is embodied as an IGBT module (insulated gate bipolar transistor module).

In one embodiment, it may be expedient to provide a plurality of conversion units. In this case, it may be expedient for the evaluation facility to be connected downstream of all conversion units.

In one embodiment, it may be provided that a plurality of digital signals is generated. In this case, it may be expedient for the evaluation facility to generate an output signal from all the digital signals together.

The apparatus is preferably embodied as an electronic circuit or as part of an electronic circuit.

In one embodiment, it may be provided that each current detection apparatus has at least one current sensing resistor-a shunt resistor, preferably two or more current sensing resistors, or a current sensor, for example a GMR sensor (giant magnetoresistive sensor) or a Hall sensor.

In one embodiment, it may be provided that the output signal corresponds to a sum of the partial currents. Herein, the digital signals that correspond to the partial currents can be added up on the digital side (of the conversion unit).

Herein, it may be advantageously provided that the evaluation facility has a digital addition component, wherein the digital addition component is configured to add the digital signals together (digitally). One advantage of this embodiment is that that the addition is not analog, but takes place digitally.

In one embodiment, it may be provided that the (digital) evaluation facility comprises an FPGA module in which the digital addition component is implemented.

It is also conceivable for a plurality of addition components to be implemented in one FPGA module.

In one embodiment, it may be provided that the addition component is embodied as a software component.

In one embodiment, it may be provided that the (digital) evaluation facility has a further conversion unit.

In one embodiment, it may be provided that the output signal bears information about the symmetry of the division of the current in the phase into the partial currents. This provides information about the symmetry of the partial currents forming the phase current.

In one embodiment, it may be provided that the (digital) evaluation facility is embodied to detect asymmetry in the division of the phase current into the partial currents, and/or a short circuit and/or a failure of one of the power semiconductor modules and/or to measure a current value.

The evaluation facility preferably enables data/information about the current flow through each power semiconductor module to be determined and made available. This data can be used for predictions, thereby saving maintenance and downtime costs.

The evaluation of partial currents by the evaluation facility makes it possible to actively influence the division of the partial currents, in particular to achieve an even division between the individual power semiconductor modules.

In one embodiment, it may be provided that the evaluation facility comprises at least one inverter component, at least one digital addition component, at least one conversion unit and at least one counter unit.

In one embodiment, it may be provided that at least one conversion unit, preferably each conversion unit, is embodied as a sigma-delta converter and the digital signal is a 1-bit data stream. This enables the analog signal to be converted into a digital signal.

In particular, it may be expedient for the sigma-delta converter to be additionally equipped with an electrical insulation function. This simultaneously enables electrical isolation of the actual current values. This enables high interference immunity of the signal for further transmission to the control unit or digital processing unit of the converter to be achieved.

Herein it may be expedient to use 50 mV or 200 mV sigma-delta converters.

A 50 mV sigma-delta converter enables the shunt resistor value, and thus also its power loss, to be significantly reduced.

In one embodiment, it may be provided that the digital addition component is embodied to output an n-bit data stream, wherein n denotes the number of parallel-connected power semiconductor modules.

In one embodiment, it may be provided that the evaluation unit is embodied to convert the n-bit data stream into a 1-bit data stream. For this purpose, the evaluation unit can comprise a conversion unit, in particular a sigma-delta converter, which converts the n-bit data stream into a 1-bit data stream.

Moreover, it may advantageously be provided that the evaluation unit is embodied to provide a clock signal in addition to the data stream. This enables better synchronization to be achieved.

The object is also achieved by an electronic assembly as mentioned in the introduction comprising at least two parallel-connected power semiconductor modules (for each phase) and at least one apparatus as described above.

In one embodiment, it may be provided that the at least two current detection apparatuses and/or the at least two conversion units are integrated into the power semiconductor modules.

The integration of the current detection apparatuses into the power semiconductor module is advantageous from the point of view of heat dissipation (cooling of the current detection apparatuses), since they can, for example, be cooled or simultaneously cooled in the same way as the power semiconductor modules.

The integration of the conversion units into the power semiconductor modules enables a very compact design.

This achieves greater compactness of the power electronics apparatus, in particular the converter, and saves installation space.

In one embodiment, it may be provided that the at least two current detection apparatuses are integrated into the power semiconductor modules and the at least two conversion units are not integrated into the power semiconductor modules. This can result in advantages in the design of the assembly since it can be designed more freely and be better adapted to specific applications. Herein, it is better to arrange the conversion units on the respective power semiconductor modules in such a way that the analog transmission path of the signal is kept as short as possible while simultaneously taking account of the problem of EMC.

In one embodiment, it may be provided that neither the at least two current detection apparatuses nor the at least two conversion units are integrated into the power semiconductor modules.

Herein, the current detection apparatuses can, for example, be embodied as separate modules (structurally separate from power semiconductor modules). This has further advantages with regard to the modularity of the structure.

Consistent modularization of the power modules and freedom in design are enabled and this results in savings in material, size, weight and development effort, and thus to lower costs.

It may be advantageously provided that the assembly comprises more than two, in particular three or more, power semiconductor modules (for each phase), wherein the number of current detection apparatuses and/or the number of conversion units are in each case equal to the number of power semiconductor modules. Herein, it may be expedient in each case for one, preferably exactly one, current detection apparatus and one, preferably exactly one, conversion unit to be provided for each power semiconductor module.

In one embodiment, it may be provided that the assembly has a carrier embodied as a printed circuit board on which the at least two parallel-connected power semiconductor modules, the at least two current detection apparatuses and the at least two conversion units are mounted. Herein, this is an assembly for one phase.

In one embodiment, it may be provided that the assembly is embodied for three phases. For this purpose, the assembly can have a carrier embodied as a printed circuit board on which at least six power semiconductor modules, two of which are connected in parallel in each case, at least six current detection apparatuses (one for each power semiconductor module) and at least six conversion units (one for each power semiconductor module) are mounted.

Herein, it may be expedient for the evaluation facility to be mounted on the carrier.

The object is also achieved by a method as mentioned in the introduction for inspecting and/or monitoring current on a phase in that
S01: a partial current is detected at each of the at least two power semiconductor modules, wherein a sum of all detected partial currents is produced in the current in the phase—the total phase current—and analog signals corresponding to the respective partial currents are generated therefrom;
S02: each analog signal is converted into a digital signal;
S03: at least one item of control-relevant and/or diagnostically relevant information about the current in the phase is determined from the digital signals, wherein the diagnostically relevant information comprises information about the symmetry of the division of the current in the phase into the partial currents and the control-relevant information comprises a current value of the phase, wherein when determining the at least one item of control-relevant information:
   S030: the digital signals are added digitally, and
   S031: the current value for the phase is determined from the result of the digital addition of the digital signals.

In one embodiment, it may be provided that when determining the at least one item of control-relevant and/or diagnostically relevant information:

In addition, information relating to asymmetry in the division of the phase current into the partial currents and/or a short circuit and/or a failure of one of the power semiconductor modules is determined.

Further features, properties and advantages of the present invention will emerge from the following description with reference to the attached figures, which show schematically in:

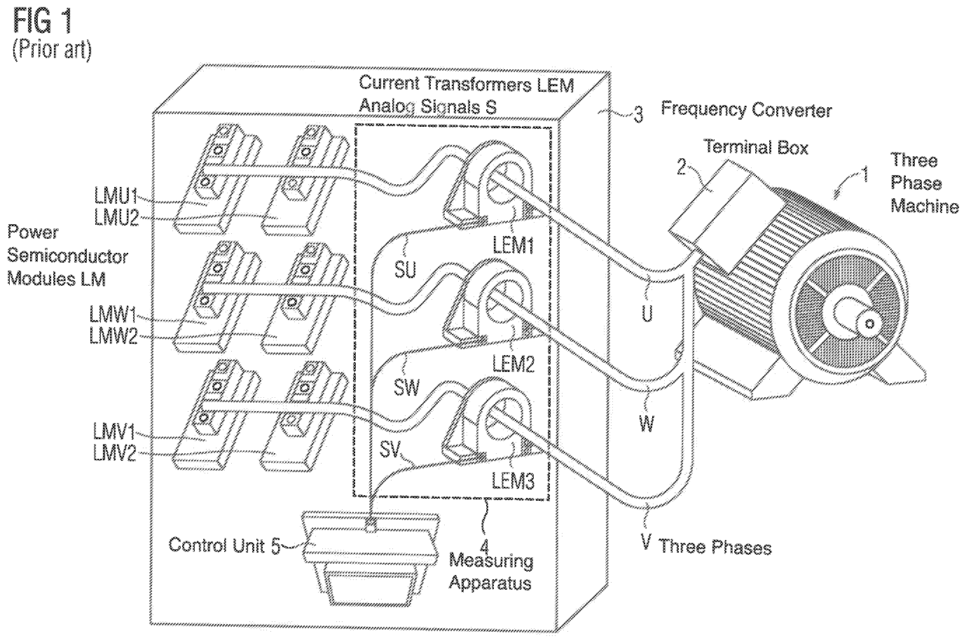

FIG. 1 a drive train according to the prior art,

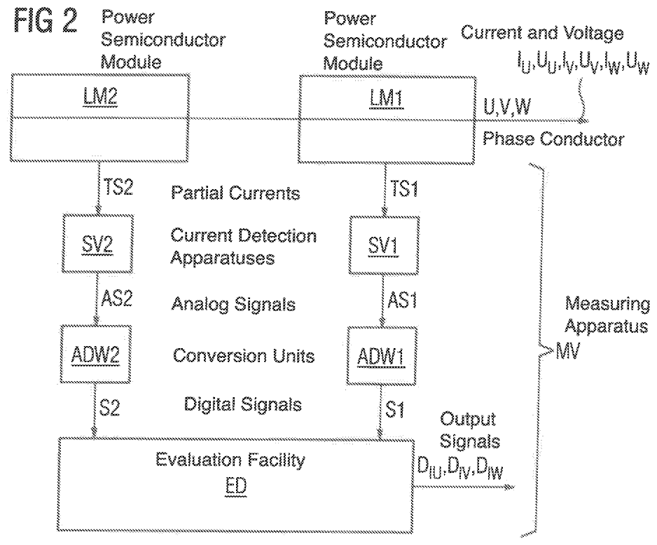

FIG. 2 a measuring apparatus for inspecting and/or monitoring current in a phase,

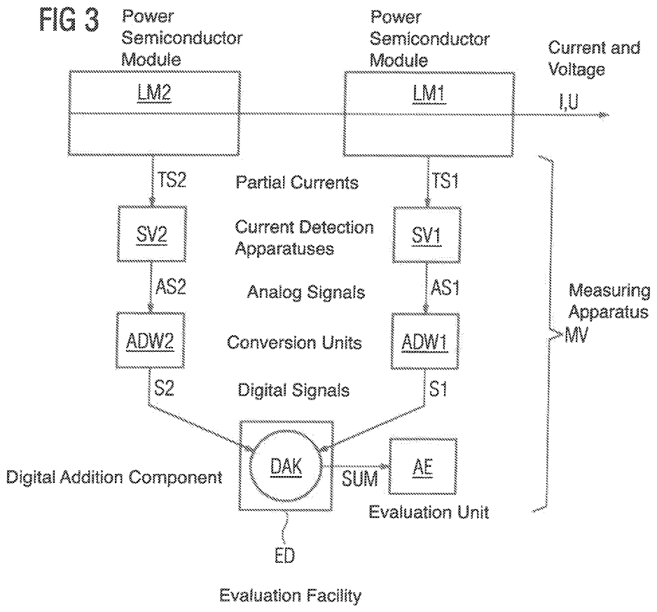

FIG. 3 an evaluation facility of the measuring apparatus in FIG. 2,

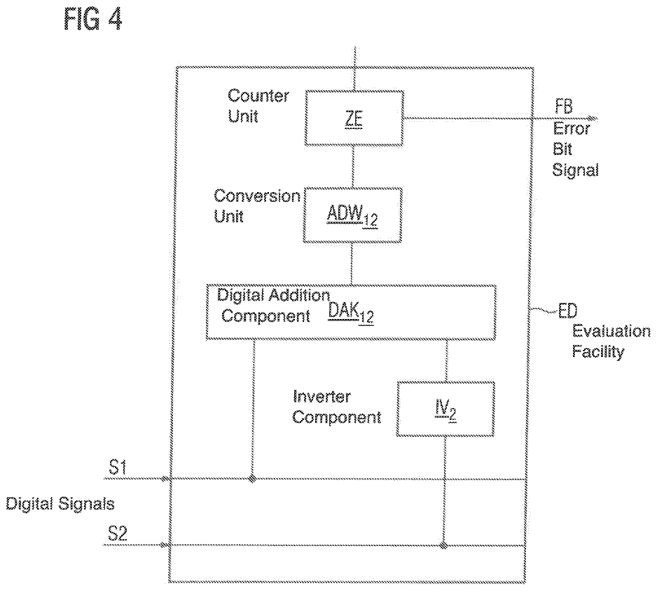

FIG. 4 a further evaluation facility,

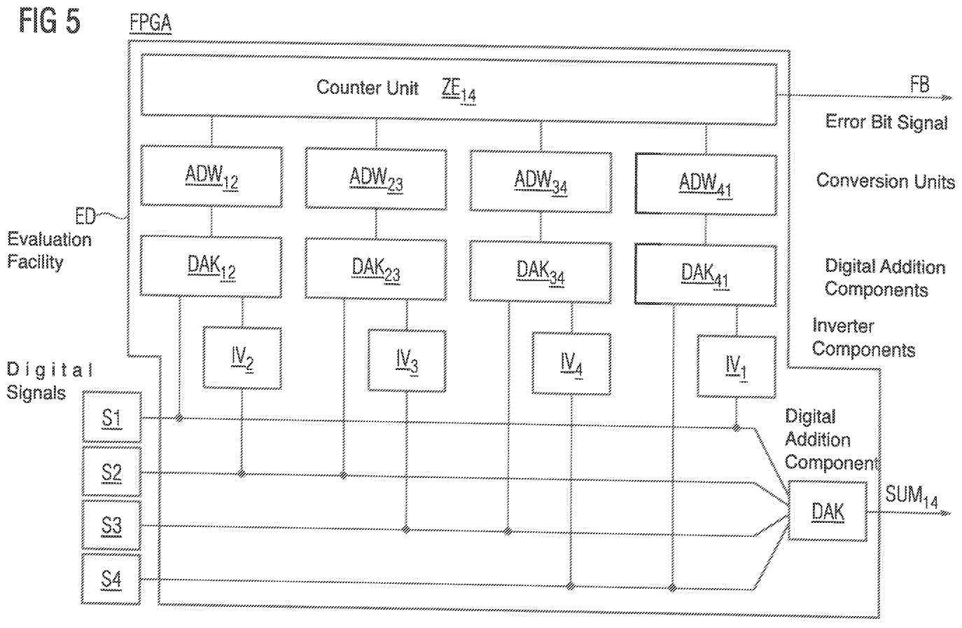

FIG. 5 an evaluation facility for detecting asymmetry in the division of the phase current into the partial currents and for measuring a current value,

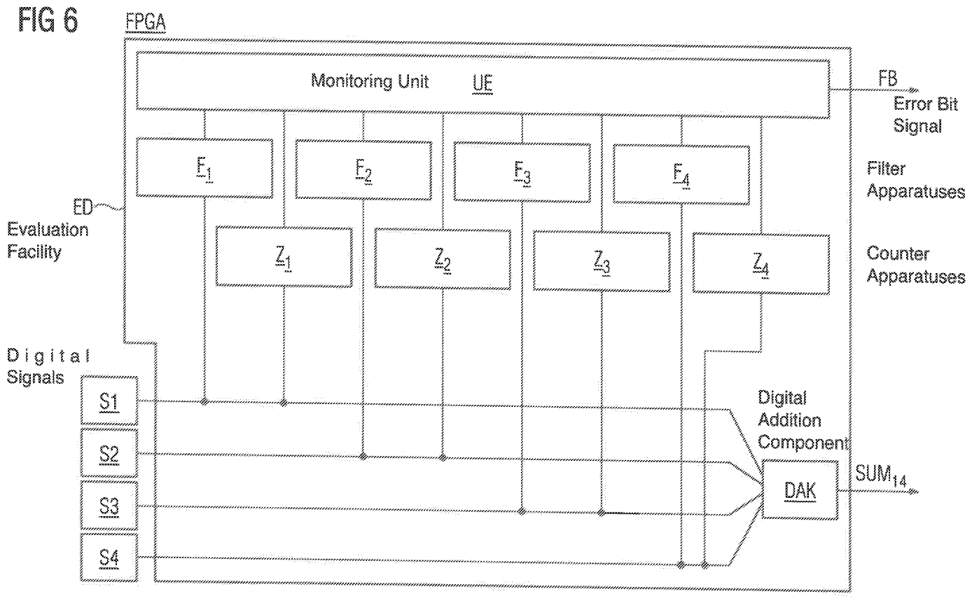

FIG. 6 an evaluation facility for detecting asymmetry in the division of the phase current into the partial currents, a short circuit, a failure of one of the power semiconductor modules and for measuring a current value,

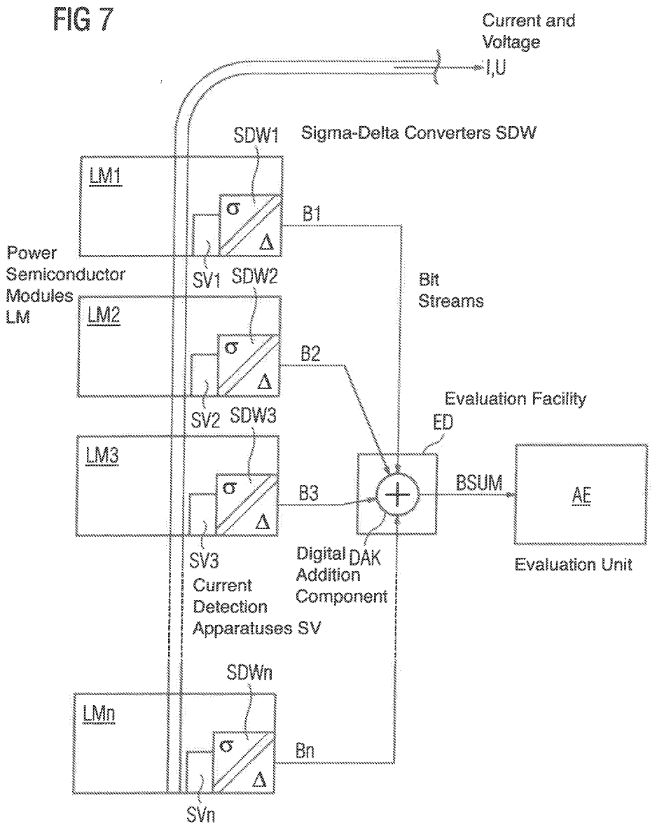

FIG. 7 a development of the measuring apparatus in FIG. 2,

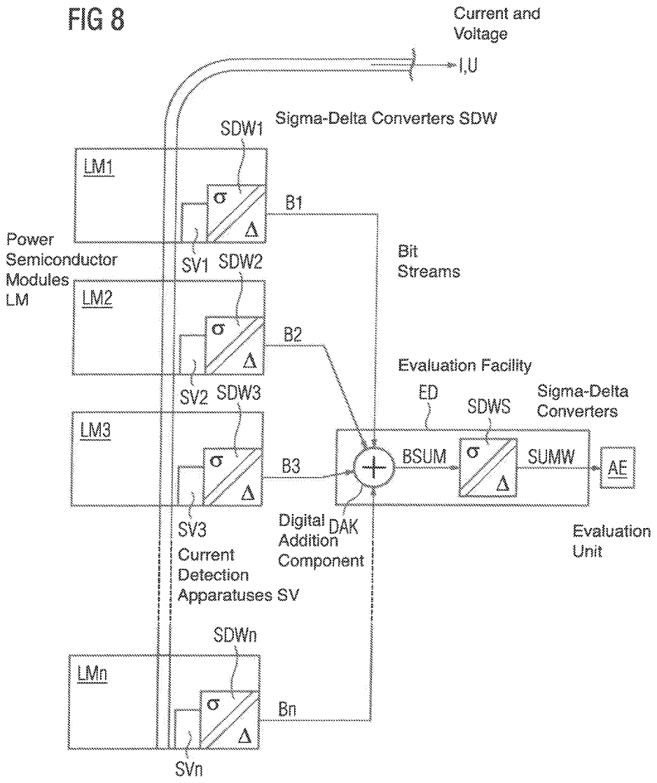

FIG. 8 a development of the evaluation facility of the measuring apparatus in FIG. 7,

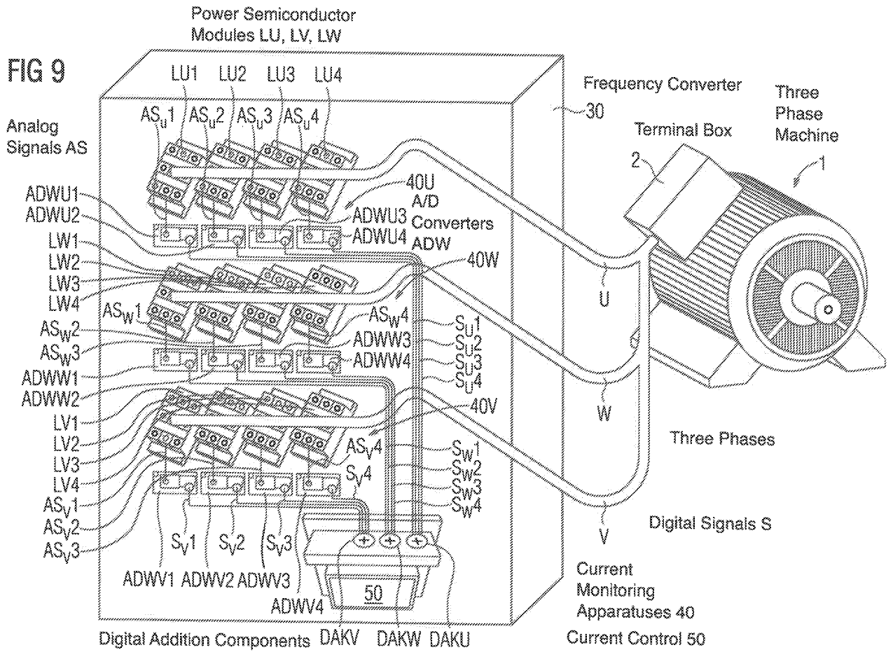

FIG. 9 an inverter-controlled three-phase machine, and

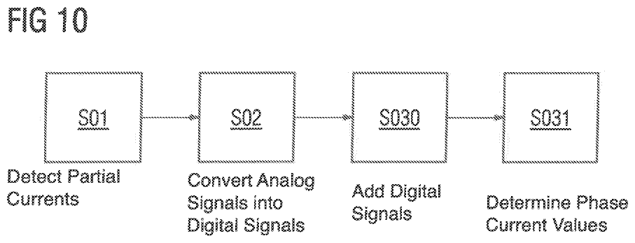

FIG. 10 a flow chart of a method for inspecting and/or monitoring current on a phase.

In the exemplary embodiments and figures, identical or identically acting elements can in each case be provided with the same reference symbols. In principle, the elements and their relative sizes are not to be regarded as true to scale; rather individual elements may be depicted proportionally larger for better visualization and/or for better understanding.

FIG. 1 (prior art) shows a three-phase machine 1. The three-phase machine 1 is connected to the three-phase alternating current or voltage. The three phases U, V, W (same frequency) are supplied to the three-phase machine 1 via the terminal box 2 and generated by a frequency converter 3 for supplying the three-phase machine 1.

The frequency converter 3 comprises a conventional measuring apparatus 4 with which phase current in each phase U, V, W can be measured and is measured during operation and supplied to a control unit 5 of the frequency converter 3 as an actual current value. The actual current value is necessary for controlling the frequency converter 3.

By way of example, the frequency converter 3 comprises six power semiconductor modules LMU1, LMU2, LMV1, LMV2, LMW1, LMW2: two power semiconductor modules for each phase U, V, W.

The power semiconductor modules LMU1, LMU2, LMV1, LMV2, LMW1, LMW2 are, for example, embodied as IGBT (insulated gate bipolar transistors) modules.

To detect the phase current, the measuring apparatus 4 comprises three current transformers LEM1, LEM2, LEM3—one transformer LEM1, LEM2, LEM3 for each phase U, V, W. The transformers can, for example, be embodied as current transformers from the company LEM, for example from the HTA-S series of direct-imaging Hall effect current sensors.

Each current transformer LEM1, LEM2, LEM3 outputs an analog signal SU, SV, SW which represents the phase current of the corresponding phase U, V, W. The analog signals SU, SV, SW are supplied to the control unit 5.

FIG. 2 shows a measuring apparatus MV which corresponds to the apparatus according to the invention for inspecting and/or monitoring current in a phase. FIG. 2 shows two power semiconductor modules LM1 and LM2 which, for example, are embodied as IGBT modules and are connected to a phase conductor U, V, M of, for example, a frequency converter (not shown here) as parallel-connected elements.

In particular, it may be provided that the power semiconductor modules LM1, LM2 are embodied to switch currents of up to 2000 A or even up to 3000 A (peak current). Modules of such sizes are typically used when the currents exceed 200 A-300 A (400 to 600 A peak current). This is, for example, the case with frequency converters that have a wide power range, for example from 0.55 kW to 250.00 kW and up to the megawatt range (for example 1.5 MW).

The phase conductor U, V. W can, for example, be one of the three phase conductors U, V, or W connected to a three-phase machine 1 and supply this with current I_{U}, I_{V}, I_{W}, and voltage U_{U}, U_{V}, U_{W}.

The measuring apparatus MV comprises—in the present example consists of—two current detection apparatuses SV1, SV2, two conversion units ADW1, ADW2 and an evaluation facility ED.

Each power semiconductor module LM1, LM2 is assigned exactly one current detection apparatus SV1, SV2. Each current detection apparatus SV1, SV2 detects a corresponding partial current TS1, TS2 which flows through the respective power semiconductor module LM1, LM2 and outputs an analog signal AS1, AS2 which represents the respective partial current TS1, TS2. Herein, the person skilled in the art will understand that the drawing is a purely schematic representation and the partial currents TS do not flow past the main current, but are part of the main current.

In one embodiment, it may be provided that each current detection apparatus SV1, SV2 has one or more (for example 2, 4, 6 or 8) current sensing resistors (shunt resistors) or is embodied as one or more shunt resistors. However, other measuring methods are also conceivable, for example using Hall sensors, etc.

It may be expedient for the current detection apparatus SV1, SV2 to be arranged directly on the exactly one power semiconductor module LM1, LM2 corresponding to this current detection apparatus SV1, SV2 or integrated in the corresponding power semiconductor module LM1, LM2. For example, the current detection apparatus SV1, SV2 and the power semiconductor module LM1, LM2 can be mounted on a common carrier, for example a common printed circuit board.

In one embodiment, it may be provided that the current detection apparatuses SV1, SV2 and the power semiconductor modules LM1, LM2 in each case have a common housing and/or are arranged on a common heat sink in each case. This results in advantages in terms of installation space and/or cooling of the current detection apparatuses SV1, SV2.

A conversion unit ADW1, ADW2 is in each case connected downstream of each current detection apparatus SV1, SV2. The conversion units ADW1, ADW2 can, for example, be embodied as A/D converters, in particular as sigma-delta converters, and are embodied to convert the respective analog signal AS1, AS2 into a digital signal S1, S2. In the case of sigma-delta converters, the digital signals S1, S2 are 1-bit data streams. Such 1-bit data streams require fewer connection lines and pins on the electronic components and therefore less space on the circuit carrier. In addition, the 1-bit data streams provide advantages for a receiver of these signals. For example, only two bits are required on the receiver (bit and clock).

Preferably, the sigma-delta converters are used with an electrical isolation function thus enabling electrical isolation of the signal at the same time as the conversion of the analog signal into the digital signal.

Preferably, the A/D converters or the sigma-delta converters are not integrated into the corresponding power semiconductor modules LM1, LM2. First of all, the area in a power semiconductor module LM1, LM2, for example in a IGBT module, is very expensive. Moreover, the integration of an A/D converter or the sigma-delta converter is a very costly and complicated process. In addition, modularity is advantageous here because, for example, the power semiconductor modules LM1, LM2 and the conversion units ADW1, ADW2 typically have different service lives.

In one embodiment, it may be provided that the conversion units ADW1, ADW2, the current detection apparatuses SV1, SV2 and the power semiconductor modules LM1, LM2 together form part of an electronic assembly and are, for example, arranged on a common printed circuit board. This enables a compact structure. Moreover, the number of plug connections is reduced. Signals can be routed very efficiently to the circuit carrier and effectively shielded due to the multilayer structure.

Thus, the digital signals S1, S2 contain information about the partial currents TS1, TS2 in the power semiconductor modules LM1, LM2. This information is, for example, not available in the prior art shown in FIG. 1.

The evaluation facility ED is connected downstream of the conversion units ADW1, ADW2. The digital signals S1, S2 are supplied to the evaluation facility ED (input). The downstream evaluation facility ED is embodied and configured, based on the digital signals S1, S2, to generate an output signal D_{Iu}, D_{Iv}, D_{Iw} (output) which bears control-relevant and/or diagnostically relevant information about the current I_{U}, I_{V}, I_{W} in the phase U, V, W.

The type of signal D_{Iu}, D_{Iv}, D_{Iw} and the information can be different. This can, for example, be a sum, in particular a sum on the digital side of the respective conversion unit, of the digital signals S1, S2 in which the control-relevant information is the current value, which can be used as the actual current value for the control apparatus of the frequency converter, or information about the symmetry of the division of the current I_{U}, I_{V}, I_{W} into the partial currents TS1, TS2. Further information is conceivable.

FIG. 3 shows an embodiment of the evaluation facility ED. The evaluation facility ED comprises a digital addition component DAK.

The digital addition component DAK is configured to add the digital signals S1, S2 together and output the sum SUM of these signals.

The digital addition component DAK can, for example, be embodied as a software component. The evaluation facility ED can, for example, comprise an FPGA module (field programmable gate array). The digital addition component DAK can be implemented in such an FPGA module.

Compared to the analog addition of partial currents, the digital addition described in the present case is in particular advantageous with high powers and currents (for example between 500 A and 5000 A for each phase).

The digital sum SUM can then be supplied to an evaluation unit AE which can be connected downstream of the evaluation facility ED, for example the FPGA module.

The evaluation unit AE can be configured to determine a current value from the sum SUM. The evaluation unit AE can then supply the current value (control-relevant information) as the actual current value to a control unit, preferably a current control unit (not shown here) of the frequency converter. In this case, the advantage of the addition component DAK is particularly evident because its use reduces the number of pins required, for example for ASIC, FPGA or controller.

The evaluation unit AE can be embodied as a digital evaluation unit, in particular as a digital evaluation circuit, for example an application-specific integrated circuit—ASIC (application-specific integrated circuit).

The digital addition of the signals S1, S2 is particularly advantageous when digital evaluation circuits, for example ASICs, are used. The number of pins is typically limited in digital evaluation circuits. At least two pins are required for each digital signal S1, S2. Herein, the number of pins is an important parameter that is difficult to influence and would increase linearly with the number of digital signals S1, S2. The digital addition unit DAK offers a simple solution to this problem.

The evaluation facility ED can moreover comprise an A/D converter, for example a sigma-delta converter, to which the digital sum SUM of the signals S1, S2 is supplied. Although such a converter is not shown in FIG. 3, it can be seen in another embodiment in FIG. 8 (the converter SDSW) and has the same function. If this converter SDSW is embodied as a sigma-delta converter, a 1-bit data stream is supplied to the evaluation unit AE. This enables the number of pins required by the evaluation unit AE to receive the signal bearing the information about the current I_{U}, I_{V}, I_{W} in the phase U, V, W to be minimized.

FIG. 4 shows a further embodiment of the evaluation facility ED. The evaluation facility ED receives the digital signals as input and generates an error bit signal FB as output. The error bit signal FB bears information about the symmetry of the division of the current I_{U}, I_{V}, I_{W} in the phase U, V, W into the partial currents TS1, TS2.

For this purpose, the evaluation facility ED can, for example, comprise the following (hardware or software) components: an inverter component IV₂, a (further) digital addition component DAK₁₂, an (optional) conversion unit ADW₁₂ and a counter unit ZE.

One or more of these components can be implemented in an FPGA module.

FIG. 4 clearly shows the function of the individual components. The inverter component IV₂ is configured to invert one of the two digital signals S1, S2—in the present case the second signal S2—and to supply the result to the digital addition component DAK₁₂, which adds the result of the inversion and the non-inverted signal—in this case, the signal S1.

The result of the addition can be supplied to an optional conversion unit ADW₁₂. The conversion unit ADW₁₂ can be embodied as an A/D converter, in particular as a sigma-delta converter.

If the digital signals S1, S2 are 1-bit data streams, the result of the addition by the digital addition component DAK₁₂ is a 2-bit data stream, which can optionally be converted into a 1-bit data stream by a sigma-delta converter.

The counter unit ZE is configured to receive the signal from the digital addition component DAK₁₂ and to evaluate it in order to detect any deviations from a symmetrical distribution of the partial currents TS1, TS2.

If the digital signals S1 and S2 are symmetrical, the result of the digital addition is zero. The counter unit ZE generates a corresponding error bit signal FB that, for example, is also equal to zero. If the digital signals S1 and S2 are asymmetrical, the result of the digital addition is different from zero. In this case, the counter unit ZE also generates a characteristic error bit signal FB.

If the conversion unit ADW₁₂ is present and embodied as a sigma-delta converter, the counter unit ZE counts zeros and ones.

It should be noted that the above-described digital addition component DAK can be implemented in the same FPGA module so that the evaluation facility ED can output two output signals simultaneously: the digital sum SUM and the error bit signal FB.

This aspect is illustrated in FIG. 5. FIG. 5 shows an extension of the embodiment of the evaluation facility ED in FIG. 4 to four digital signals S1, S2, S3, S4, wherein the evaluation facility ED has four inverter components IV₁, IV₂, IV₃, IV₄, four further digital addition component DAK₁₂, DAK₂₃, DAK₃₄, DAK₄₁, and four (optional) conversion units ADW₁₂, ADW₂₃, ADW₃₄, ADW₄₁ and is configured to check the symmetry of the current distribution between the digital signals S1 to S4 by inspecting them cyclically in pairs. Herein, each signal pair S1-S2, S2-S3, S3-S4, S4-S1 is added up as described with reference to FIG. 4.

The counter unit ZE₁₄ is for example configured to receive the signals from the digital addition component DAK₁₂, DAK₂₃, DAK₃₄, DAK₄₁, and evaluate them in order to detect any deviations from a symmetrical distribution of the four partial currents.

Moreover, the evaluation facility ED in FIG. 5 comprises the digital addition component DAK which adds the digital signals S1 to S4 together and supplies the digital sum SUM₁₄, for example with prior modulation by an A/D converter and in particular by a sigma-delta converter, to the evaluation unit AE (not shown here).

The evaluation facility ED is, for example, embodied as an FPGA module.

The evaluation facility ED can, for example, have one or more interfaces that support one or more communication protocols, for example SPI and/or I2C. These interfaces can be part of the FPGA module.

FIG. 6 shows a further embodiment of the evaluation facility ED for monitoring the symmetry of the division of the phase current I_{U}, I_{V}, I_{W} into the corresponding partial currents.

The evaluation facility ED is therefore embodied to detect asymmetry in the division of the phase current I_{U}, I_{V}, I_{W} into the partial currents. Moreover, the evaluation facility ED can additionally or alternatively be embodied to detect a short circuit, a failure of one of the (here four) power semiconductor modules, and to output a signal SUM₁₄ for an immediate current value measurement.

The evaluation facility ED, which is here likewise embodied as an FPGA module, provides a counter apparatus Z1, Z2, 23, 24 and a filter apparatus F1, F2, F3, F4 for each digital signal S1, S2, S3, S4 coming from each power semiconductor module. Each filter apparatus is preferably configured to convert the serial sigma-delta data stream supplied to the respective filter apparatus into in a “digital value” of the current value of the current, for example 1024 (bit value). Each counter apparatus is preferably configured to monitor the bit stream for consecutive ones. If the number of successive ones exceeds a predefined limit, this can mean that the measured current is too high and it must be assumed that there is a fault.

The results of the counting and filtering can then be supplied to a monitoring unit UE which monitors the system for symmetry, short circuit, failure of one or more digital signals S1, S2, S3, S4, etc. and is able to detect them. If, for example 10 consecutive ones are counted, this can be defined as an overcurrent event so that a short circuit can be inferred with a high degree of probability.

Obviously, it is easy to increase the number of power semiconductor modules and thus the digital signals shown in FIGS. 4-6. This means that it is equally possible for five, six, seven, eight etc. power semiconductor modules to be provided for each phase and five, six, seven, eight etc. digital signals can be processed and examined in order to determine asymmetry in the division of the phase current into the partial currents I_{U}, I_{V}, I_{W} and to output a signal SUM₁₄ for an immediate current value measurement.

The information as to whether the division of the currents is symmetrical or asymmetrical can, for example, be used for predictive maintenance. In this respect, this information is diagnostically relevant.

Asymmetrical division of the currents S1, S2, S3, S4 etc. between the parallel-connected power modules LM1, LM2, . . . can lead to a high load on individual power modules LM1, LM2, . . . in the parallel circuit. A higher load in turn reduces the service life of the power module with a higher current and can lead to premature failure. The higher load on a power module can only be detected with difficulty with conventional methods since no information is available about the current distribution between the parallel-connected power modules LM1, LM2, . . . . Depending on the level of asymmetry, a failure may only occur after a long time (months or years).

The information contained in the error bit signal FB about the symmetry of the division of the current I_{U}, I_{V}, I_{W} in the phase U, V, W into the partial currents TS1, TS2 can be used to monitor the partial currents TS1, TS2 for asymmetry and to generate a message long before a failure (predictively) to the effect that an undesirable operating state is present and that maintenance and inspection should be carried out by a service technician.

It should be noted that the inspection and/or monitoring described in the present disclosure is performed continuously during operation. For example, the digital signals continuously checked for symmetry and/or digitally added.

FIG. 7 shows a development of the measuring apparatus MV in FIG. 2 for the general case where n parallel-connected power semiconductor modules, embodied for example as IGBT modules, are provided for each phase U, V, W, wherein n=2, 3, 4, 5, 6, . . . 10, . . . .

In each case, one current detection apparatus SV1, SV2, . . . SVn is provided for each power semiconductor module LM1, LM2, . . . LMn and, for example, integrated into the corresponding power semiconductor module LM1, LM2, . . . LMn.

In the present case, the A/D converters are embodied as sigma-delta converters SDW1, SDW2, . . . SDWn. The number n of sigma-delta converters is equal to the number n of power semiconductor modules and current detection apparatuses. In each case, one sigma-delta converter SDW1, SDW2, . . . SDWn is provided for each semiconductor module LM1, LM2, . . . LMn or each current detection apparatus SV1, SV2, . . . SVn.

The sigma-delta converters SDW1, SDW2, . . . SDWn are, for example, integrated into the corresponding power semiconductor modules LM1, LM2, . . . LMn (but do not have to be), but are preferably located in the vicinity of the corresponding power semiconductor module, for example on a common carrier embodied as a printed circuit board.

The signal at the output of each sigma-delta converter SDW1, SDW2, . . . SDWn is a 1-bit data stream B1, B2, . . . Bn.

The digital addition component DAK adds up the 1-bit data streams B1, B2, . . . Bn and supplies an n-bit data stream BSUM to the evaluation unit AE. The evaluation facility ED thus comprises the digital addition component DAK. The evaluation facility ED can be embodied as an FPGA module.

One or more of the current detection apparatuses SV1, SV2, . . . SVn can comprise one or more shunt resistors. Combined with the digital addition, which is performed by the digital addition component DAK, this has particular advantages with regard to interference immunity and transmission to the control unit.

FIG. 8 shows that the evaluation facility ED can comprise a further sigma-delta converter SDWS. The sigma-delta converter SDWS is connected downstream of the digital addition component DAK and is embodied to convert the n-bit data stream BSUM into a 1-bit data stream SUMW which is supplied to the evaluation unit AE. The evaluation unit AE determines an actual current value from the 1-bit data stream SUMW and supplies it to the control unit of the frequency converter.

FIG. 9 shows a three-phase machine 1 which is supplied by a frequency converter 30. The phases U, V, W are connected in the terminal box 2.

The frequency converter 30 has a total of twelve power semiconductor modules, embodied for example as IGBT-modules—four parallel-connected power semiconductor modules for each phase: LU1, LU2, LU3, LU4 for the U phase, LV1, LV2, LV3, LV4 for the V phase, and LW1, LW2, LW3, LW4 for the W phase.

FIG. 9 shows that the frequency converter 30 comprises three apparatuses 40U, 40V, 40W, wherein each apparatus 40U, 40V, 40W is provided for inspecting and/or monitoring the current at the respective phase U, V, W.

Together with the corresponding power semiconductor modules LU1, LU2, LU3, LU4; LV1, LV2, LV3, LV4; LW1, LW2, LW3, LW4, each apparatus 40U, 40V, 40W can, for example, form an electronic assembly and thus be mounted on a common carrier, which is, for example, embodied as a printed circuit board.

The current detection apparatuses are integrated into the respective power semiconductor modules and are not visible in FIG. 9. The figure shows the analog signals AS_{U}1, AS_{U}2, AS_{U}3, AS_{U}4, AS_{W}1, AS_{W}2, AS_{W}3, AS_{W}4, AS_{V}1, AS_{V}2, AS_{V}3, AS_{V}4 which are output by the respective current detection apparatuses (not shown here for reasons of space). The analog signals AS_{U}1, AS_{U}2, AS_{U}3, AS_{U}4, AS_{W}1, AS_{W}2, AS_{W}3, AS_{W}4, AS_{V}1, AS_{V}2, AS_{V}3, AS_{V}4 are supplied to the corresponding A/D converters ADWU1, ADWU2, ADWU3, ADWU4, ADWW1, ADWW2, ADWW3, ADWW4, ADWV1, ADWV2, ADWV3, ADWV4 of which there are in turn four for each phase U, V, W.

FIG. 9 shows that each power semiconductor module LU1, LU2, LU3, LU4, LV1, LV2, LV3, LV4, LW1, LW2, LW3, LW4 in each case corresponds to exactly one A/D converter ADWU1, ADWU2, ADWU3, ADWU4, ADWW1, ADWW2, ADWW3, ADWW4, ADWV1, ADWV2, ADWV3, ADWV4 in order to convert um the corresponding analog signal AS_{U}1, AS_{U}2, AS_{U}3, AS_{U}4, AS_{W}1, AS_{W}2, AS_{W}3, AS_{W}4, AS_{V}1, AS_{V}2, AS_{V}3, AS_{V}4 into the corresponding digital signal S_{U}1, S_{U}2, S_{U}3, S_{U}4, S_{W}1, S_{W}2, S_{W}3, S_{W}4, S_{V}1, S_{V}2, S_{V}3, S_{V}4.

The digital signals corresponding to a specific phase—here four digital signals AS_{X}1, AS_{X}2, AS_{X}3, AS_{X}4 for each phase, wherein X=U, V, W—are supplied to the corresponding digital addition component DAKU, DAKW, DAKV.

The number of digital signals for each phase is preferably equal to the number of parallel-connected power semiconductor modules.

The digital signals are, for example, 1-bit data streams.

FIG. 9 shows the respective digital addition components DAKU, DAKW, DAKV. These add the corresponding digital signals and supply the sum to a control unit 50.

As already discussed, one or more digital addition components can be implemented DAKU, DAKW, DAKV in an FPGA module, which optionally comprises a sigma-delta converter in order to generate a 1-bit data stream from an n-bit data stream, which can be supplied to an ASIC, a (further) FPGA module or a controller (evaluation unit). The current control 50 of the frequency converter 30 can thus be provided with the actual current value by the ASIC.

FIG. 10 shows a flow chart of a method for inspecting and/or monitoring current on a phase. Herein, for example, an apparatus as shown in FIGS. 2 to 9 can be used.

In a step S01, a partial current is detected at each of the at least two power semiconductor modules. Herein, (at least two) analog signals are generated, wherein each analog signal corresponds to the respective partial current or represents the respective partial current. Preferably, exactly one analog signal is generated for each power semiconductor module in each case.

In a step S02, each analog signal is converted into a digital signal. Herein, the analog signal is preferably electrically isolated.

In a step S030, the digital signals can be digitally added in order to generate a digital signal sum.

In a step S031, a current value for the phase is determined from the digital signal sum.

Alternatively or in addition to the steps S030, S031, information about the symmetry of the division of the phase current into the partial currents can be determined from the parallel digital signals and be used for inspecting and/or monitoring the phase current and thus the “state of health” of the individual power semiconductor modules. It can also be used to draw conclusions about the state of health of the overall system, for example screw connections in the current flow path, thermal contact heat sink, contamination of heat sink, fan performance etc.

When monitoring symmetry, a threshold value can, for example, be defined and a log kept of the times when it is exceeded. Herein, a distinction can, for example, be made between dynamic and static overshooting. Dynamic (short-term during switching operations): larger asymmetries can be permitted (for example up to 30%). Stationary (after the switching operation and the settling of the transient process): the asymmetry should be lower (for example <5%). In addition to logging that the threshold value has been exceeded, it is also possible to log the number of times this has happened and, preferably, in which partial current this has occurred in order to better localize the fault. It is also possible to record the amount by which the value is exceeded and the time at which this occurred.

In addition, it is conceivable that the information determined about the partial currents (value, symmetry of distribution, etc.) is assigned to a (for example trained) service life model of the power semiconductor modules, which determines the extent to which the service life is reduced or what the remaining service life is. If the remaining service life falls below a critical (predetermined) threshold value, a warning can be generated and a service call can be planned (predictively).

Although the invention has been illustrated and described in greater detall by the preferred exemplary embodiment, the invention is not restricted by the disclosed examples. Variations can be derived herefrom by the person skilled in the art without departing from the scope of protection of the invention as described by the following claims.

1-18. (canceled)

19. Apparatus for inspecting and/or monitoring a current in a phase, the apparatus comprising:
a power electronics apparatus comprising at least two power semiconductor modules connected in parallel on the phase;
at least two current detection apparatuses, each current detection apparatus configured to detect a partial current at a power semiconductor module of the power semiconductor modules connected in parallel on the phase and to output an analog signal which corresponds to the detected partial current, and a sum of all detected partial currents is produced in the current in the phase;
at least two conversion units, each conversion unit connected downstream of a current detection apparatus and configured to convert the analog signal into a digital signal; and
an evaluation facility connected downstream of the at least two conversion unit and configured to generate, based on the digital signals, at least one output signal which contains control-relevant and/or diagnostically relevant information about the current in the phase, the evaluation facility comprising a digital addition component configured to add the digital signals together so that the control-relevant information comprises the current value of the phase and the diagnostically relevant information about the current of the phase comprises information about symmetry of a division of the current in the phase into the partial currents.

20. The apparatus of claim 19, wherein each current detection apparatus has at least one current sensing resistor, or two or more current sensing resistors, or a current sensor, or a GMR sensor, or a Hall sensor.

21. The apparatus of claim 19, wherein at least one power semiconductor module is embodied as an IGBT module.

22. The apparatus of claim 21, wherein each power semiconductor module is embodied as an IGBT module.

23. The apparatus of claim 19, wherein the evaluation facility has a further conversion unit.

24. The apparatus of claim 19, wherein the output signal bears.

25. The apparatus of claim 19, wherein at least one conversion unit is embodied as a sigma-delta converter which outputs a 1-bit data stream.

26. The apparatus of claim 25, wherein each conversion unit, is embodied as a sigma-delta converter which outputs a 1-bit data stream.

27. The apparatus of claim 19, wherein the evaluation facility comprises an FPGA module in which the digital addition component is implemented.

28. The apparatus according of the claim 19, wherein the digital addition component is configured to output an n-bit data stream, wherein n is a number of parallel-connected power semiconductor modules.

29. The apparatus of claim 28, wherein the evaluation facility is configured to convert the n-bit data stream into a 1-bit data stream.

30. The apparatus of claim 29, wherein the evaluation facility is configured to provide a clock signal in addition to the 1-bit data stream.

31. An electronic assembly, comprising the apparatus of claim 19.

32. The assembly of claim 31, wherein the at least two current detection apparatuses and/or the at least two conversion units are integrated into the power semiconductor modules.

33. The assembly of claim 31, further comprising more than two power semiconductor modules, wherein a number of current detection apparatuses and a number of conversion units are equal to a number of power semiconductor modules.

34. The assembly of the claim 31, further comprising a carrier embodied as a printed circuit board on which the at least two parallel-connected power semiconductor modules, the at least two current detection apparatuses, and the at least two conversion units are mounted.

35. The assembly of claim 34, wherein the evaluation facility is mounted on the carrier.

36. A converter, comprising the electronic assembly of the claim 31.

37. The converter of claim 36, wherein the converter comprises a frequency converter

38. A method for inspecting and/or monitoring a current on a phase, wherein at least two power semiconductor modules are connected in parallel on the phase, the method comprising:
detecting a partial current at each of the at least two power semiconductor modules;
producing a sum of all detected partial currents in the current in the phase;
generating analog signals corresponding to the respective partial currents;
converting the analog signal into digital signals;
determining by digital addition of the digital signals at least one item of control-relevant and/or diagnostically relevant information about the current in the phase, wherein the diagnostically relevant information comprises information about symmetry of division of the current in the phase into the partial currents and the control-relevant information comprises a current value of the phase; and
determining a current value for the phase from the result of the digital addition of the digital signals.
